(19) United States
(12) Patent Application Publication
(10) Pub. No.: US 2025/0007238 A1
(43) Pub. Date: Jan. 2, 2025

(54) STEADY STATE LASER DIODE FINGERPRINT MEASUREMENT AND COMPENSATION

(71) Applicant: Western Digital Technologies, Inc., San Jose, CA (US)

(72) Inventors: Sukumar Rajauria, San Jose, CA (US); Erhard Schreck, San Jose, CA (US)

(21) Appl. No.: 18/447,552

(22) Filed: Aug. 10, 2023

Related U.S. Application Data
(60) Provisional application No. 63/510,386, filed on Jun. 27, 2023.

(51) Int. Cl. H01S 5/023; G11B 5/012; G11B 5/29; G11B 5/596; H01S 5/06; H01S 5/068

(52) U.S. Cl. CPC H01S 5/023; G11B 5/012; G11B 5/29; G11B 5/59688; H01S 5/0612; H01S 5/06812

(57) ABSTRACT

A data storage device may include one or more disks, an actuator arm assembly comprising one or more magnetic recording heads, at least one laser diode, and one or more processing devices configured to: set the at least one laser diode to a first temperature; apply a first forward bias and supply a first current to the at least one laser diode such that it is in a lasing state; measure, for the at least one laser diode, a first output corresponding to the first temperature and current; set the at least one laser diode to a second temperature; measure, for the at least one laser diode, a second output corresponding to the second temperature and the first current; and determine an output profile for the at least one laser diode, based at least in part on the respective output at the first temperature and the second temperature.

### CLAIM OF PRIORITY UNDER 35 U.S.C. § 120

The present Application for Patent claims priority to Provisional Application No. 63/510,386 entitled “STEADY STATE LASER DIODE FINGERPRINT MEASUREMENT AND COMPENSATION” filed Jun. 27, 2023, and assigned to the assignee hereof and hereby expressly incorporated by reference herein.

### BACKGROUND

Data storage devices such as disk drives comprise one or more disks, and one or more read/write heads connected to distal ends of actuator arms, which are rotated by actuators (e.g., a voice coil motor, one or more fine actuators) to position the heads radially over surfaces of the disks, at carefully controlled fly heights over the disk surfaces. The disk surfaces each comprise a plurality of radially spaced, concentric tracks for recording user data sectors and servo wedges or servo sectors. The servo tracks are written on previously blank disk drive surfaces as part of the final stage of preparation of the disk drive. The servo sectors comprise head positioning information (e.g., a track address) which is read by the heads and processed by a servo control system to control the actuator arms as they seek from track to track.

FIG. 1A shows a prior art disk format 2 as comprising a number of radially-spaced, concentric servo tracks 4 defined by servo wedges 6₀-6_{N} recorded around the circumference of each servo track. A plurality of concentric data tracks are defined relative to the servo tracks 4, wherein the data tracks may have the same or a different radial density (e.g., tracks per inch (TPI)) than the servo tracks 6. Each servo wedge 6ᵢ comprises a preamble 8 for storing a periodic pattern, which allows proper gain adjustment and timing synchronization of the read signal, and a sync mark 10 for storing a special pattern used to symbol synchronize to a servo data field 12. The servo data field 12 stores coarse head positioning information, such as a servo track address, used to position the head over a target data track during a seek operation. Each servo wedge (e.g., servo wedge 6₄) further comprises groups of phase-based servo bursts 14 (e.g., N and Q servo bursts), which are recorded with a predetermined phase relative to one another and relative to the servo track centerlines.

The coarse head position information is processed to position a head over a target data track during a seek operation, and the servo bursts 14 provide fine head position information used for centerline tracking while accessing a data track during write/read operations. A position error signal (PES) is generated by reading the servo bursts 14, wherein the PES represents a measured position of the head relative to a centerline of a target servo track. A servo controller processes the PES to generate a control signal applied to the one or more actuators in order to actuate the head radially over the disk in a direction that reduces the PES.

The description provided in the background section should not be assumed to be prior art merely because it is mentioned in or associated with the background section. The background section may include information that describes one or more aspects of the subject technology.

### SUMMARY

The following presents a summary relating to one or more aspects and/or embodiments disclosed herein. The following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

In some cases, the output of a laser diode, such as those used in heat assisted magnetic recording (HAMR) drivers, is dependent on a multitude of factors. Some non-limiting examples of factors include the mode in which the laser diode operates in a steady state condition, the temperature of the laser diode, the ambient temperature surrounding the laser diode (or the temperature in which the laser diode operates), and/or the laser current supplied to the laser diode. In some cases, the laser diode temperature can change significantly during operation. For instance, the laser diode temperature can be affected by self-heating induced in the laser diode (e.g., laser diode may heat up when it is reverse biased, when it is forward biased and in a lasing state, etc.), temperature increase of thermal fly height control (TFC) element, temperature of writer element, ambient temperature, etc. Since the laser output (i.e., optical output of the laser diode when it is in a lasing state, where optical output may refer to power, wavelength, and/or frequency of light emitted by laser diode) is dependent on laser current and laser diode temperature, laser diodes often experience abrupt changes in laser output as the temperature changes. In some circumstances, on the fly measurement of laser optical output at different temperatures may be desired to help maintain a constant output power from the laser. This can help enhance disk drive operations by allowing the optical output power from the laser diode to be kept constant or substantially constant across a range of temperatures and for different modes.

Some aspects of the present disclosure are directed to a technique for measuring a laser diode fingerprint, for instance, when the laser diode is in steady state. Additionally, some aspects of the disclosure are also directed to utilizing the steady state laser diode fingerprint information for compensating or adjusting the laser current supplied to the laser diode to maintain a constant or substantially constant optical output power from the laser diode. As used herein, the terms “fingerprint profile”, “power output profile”, or “output profile” may be used interchangeably throughout the disclosure.

In some aspects, the techniques described herein relate to a data storage device, including: one or more disks; an actuator arm assembly including one or more magnetic recording heads; at least one laser diode; and one or more processing devices configured to: set the at least one laser diode to a first temperature; apply a first forward bias to the at least one laser diode such that the at least one laser diode is in a lasing state, wherein applying the first forward bias further includes supplying a first current to the at least one laser diode; measure a first optical power output of the at least one laser diode, wherein the first optical power output corresponds to the first temperature and the first current; set the at least one laser diode to a second temperature; measure a second optical power output of the at least one laser diode, wherein the second optical power output corresponds to the second temperature and the first current; and determine a power output profile for the at least one laser diode, based at least in part on the respective optical power output at the first temperature and the second temperature.

In some aspects, the techniques described herein relate to a data storage device, wherein the one or more processing devices are further configured to: set the at least one laser diode to a third temperature; and measure a third optical power output of the at least one laser diode, wherein the third optical power output corresponds to the third temperature and the first current; and wherein determining the power output profile for the at least one laser diode is further based on the third optical power output at the third temperature.

In some aspects, the techniques described herein relate to a data storage device, wherein determining the power output profile for the at least one laser diode is based at least in part on sweeping the at least one laser diode through a plurality of temperatures and measuring a corresponding optical power output for each of the plurality of temperatures, including at least the first, second, and third temperatures, and wherein the power output profile is specific to the first current.

In some aspects, the techniques described herein relate to a data storage device, wherein: setting the at least one laser diode to the first temperature includes applying a first reverse bias to the at least one laser diode to preheat the at least one laser diode to the first temperature; and setting the at least one laser diode to the second temperature includes applying a second reverse bias to the at least one laser diode to preheat the at least one laser diode to the second temperature.

In some aspects, the techniques described herein relate to a data storage device, wherein the one or more processing devices are further configured to: preheat the at least one laser diode to the first temperature prior to applying the first forward bias; and apply the first forward bias to the at least one laser diode, based at least in part on preheating the at least one laser diode to the second temperature and prior to measuring the second optical power output.

In some aspects, the techniques described herein relate to a data storage device, wherein the one or more processing devices are further configured to: determine one or more other power output profiles for the at least one laser diode, based at least in part on sweeping the at least one laser diode through a plurality of temperatures and measuring a corresponding optical power output for each of the plurality of temperatures, wherein each of the one or more power output profiles is associated with one or more of a different forward bias and a different current.

In some aspects, the techniques described herein relate to a data storage device, wherein the one or more processing devices are further configured to: select an optical power output for a write operation, wherein the write operation is associated with a steady state temperature; and initiate the write operation by activating a magnetic recording head corresponding to a first one of the at least one laser diode, applying a forward bias to the first laser diode, and supplying a first laser current to the first laser diode. In some aspects of the data storage device, the one or more hardware processors are further configured to monitor an optical power output of the first laser diode; and determine whether the optical power output of the first laser diode is different from the optical power output selected for the write operation.

In some aspects, the techniques described herein relate to a data storage device, wherein the one or more processing devices are further configured to: adjust the first laser current supplied to the first laser diode, based at least in part on determining the optical power output of the first laser diode is different from the optical power output selected for the write operation, and wherein the adjusting the first laser current is based at least in part on determining the one or more power output profiles.

In some aspects, the techniques described herein relate to a data storage device, wherein, prior to adjusting the first laser current supplied to the first laser diode, the one or more processing devices are further configured to: identify, from the one or more power output profiles, a power output profile associated with the magnetic recording head and first laser diode.

In some aspects, the techniques described herein relate to a data storage device, wherein the one or more processing devices are further configured to: adjust the first laser current to minimize or reduce variations in the optical power output of the first laser diode relative to the optical power output selected for the write operation.

In some aspects, the techniques described herein relate to a data storage device, wherein setting the at least one laser diode includes using at least one of an extrinsic heater and an antiparallel diode on the at least one laser diode to preheat the at least one diode to a respective one of the first temperature and the second temperature.

In some aspects, the techniques described herein relate to a data storage device, wherein the at least one laser diode includes a plurality of laser diodes and the one or more magnetic recording heads include a plurality of magnetic recording heads, each magnetic recording head corresponding to one of the plurality of laser diodes, and wherein the one or more processing devices are further configured to: measure an optical power output for each pair of magnetic recording head and laser diode for a plurality of temperatures, the plurality of temperatures including at least the first temperature and the second temperature; and determine a relation between optical power output and temperature for each pair of magnetic recording head and laser diode for a plurality of currents.

In some aspects, the techniques described herein relate to a method for operating a data storage device, including: setting at least one laser diode to a first temperature; applying a first forward bias to the at least one laser diode such that the at least one laser diode is in a lasing state, wherein applying the first forward bias further includes supplying a first current to the at least one laser diode; measuring a first optical power output of the at least one laser diode, wherein the first optical power output corresponds to the first temperature and the first current; setting the at least one laser diode to a second temperature; measuring a second optical power output of the at least one laser diode, wherein the second optical power output corresponds to the second temperature and the first current; and determine a power output profile for the at least one laser diode for the first current, based at least in part on the respective optical power output at the first temperature and the second temperature.

In some aspects, the techniques described herein relate to a method, further including setting the at least one laser diode to a third temperature; and measuring a third optical power output of the at least one laser diode, wherein the third optical power output corresponds to the third temperature and the first current; and wherein determining the power output profile for the at least one laser diode is further based on the third optical power output at the third temperature.

In some aspects, the techniques described herein relate to a method, wherein determining the power output profile for the at least one laser diode is based at least in part on sweeping the at least one laser diode through a plurality of temperatures and measuring a corresponding optical power output for each of the plurality of temperatures, including at least the first, second, and third temperatures, and wherein the power output profile is specific to the first current.

In some aspects, the techniques described herein relate to a method, wherein: setting the at least one laser diode to the first temperature includes applying a first reverse bias to the at least one laser diode to preheat the at least one laser diode to the first temperature; and setting the at least one laser diode to the second temperature includes applying a second reverse bias to the at least one laser diode to preheat the at least one laser diode to the second temperature.

In some aspects, the techniques described herein relate to a method, further including: determining one or more other power output profiles for the at least one laser diode, based at least in part on sweeping the at least one laser diode through a plurality of temperatures and measuring a corresponding optical power output for each of the plurality of temperatures, wherein each of the one or more power output profiles is associated with one or more of a different forward bias and a different current.

In some aspects, the techniques described herein relate to a method, further including selecting an optical power output for a write operation, wherein the write operation is associated with a steady state temperature; initiating the write operation by activating a magnetic recording head corresponding to a first one of the at least one laser diode, applying a forward bias to the first laser diode, and supplying a first laser current to the first laser diode; monitoring an optical power output of the first laser diode; and determining whether the optical power output of the first laser diode is different from the optical power output selected for the write operation.

In some aspects, the techniques described herein relate to a method, further including: adjusting the first laser current supplied to the first laser diode, based at least in part on determining the optical power output of the first laser diode is different from the optical power output selected for the write operation, and wherein the adjusting the first laser current is based at least in part on determining the one or more power output profiles.

In some aspects, the techniques described herein relate to one or more processing devices, including: means for setting at least one laser diode to a first temperature; means for applying a first forward bias to the at least one laser diode such that the at least one laser diode is in a lasing state, wherein applying the first forward bias further includes supplying a first current to the at least one laser diode; means for measuring a first optical power output of the at least one laser diode, wherein the first optical power output corresponds to the first temperature and the first current; means for setting the at least one laser diode to a second temperature; means for measuring a second optical power output of the at least one laser diode, wherein the second optical power output corresponds to the second temperature and the first current; and means for determining a power output profile for the at least one laser diode for the first current, based at least in part on the respective optical power output at the first temperature and the second temperature.

Various further aspects are depicted in the accompanying figures and described below and will be further apparent based thereon.

### BRIEF DESCRIPTION OF THE DRAWINGS

Various features and advantages of the technology of the present disclosure will be apparent from the following description of particular examples of those technologies, and as illustrated in the accompanying drawings. The drawings are not necessarily to scale; the emphasis instead is placed on illustrating the principles of the technological concepts. In the drawings, like reference characters may refer to the same parts throughout the different views. The drawings depict only illustrative examples of the present disclosure and are not limiting in scope.

FIG. 1A shows a disk format as comprising a number of radially-spaced, concentric servo tracks defined by servo wedges recorded around the circumference of each servo track, according to various aspects of the present disclosure.

FIG. 1B shows a block diagram illustration of selected components of a disk drive, according to various aspects of the present disclosure.

FIGS. 2A and 2B illustrate conceptual block diagrams of a top view and a side view of a data storage device in the form of a disk drive, according to various aspects of the present disclosure.

FIG. 2C illustrates a method that a data storage device may perform, execute, and implement, according to various aspects of the present disclosure.

FIG. 3 illustrates another example of a method that a data storage device may perform, execute, and implement, according to various aspects of the present disclosure.

FIGS. 4A-4C illustrate conceptual graphs showing output signal against temperature for three laser diodes, each associated with a different magnetic recording head of a data storage device, according to various aspects of the disclosure.

FIG. 5 illustrates a conceptual graph showing voltage against time for a laser diode, including different reverse bias levels used to preheat the laser diode to different temperatures, for mode hop fingerprint measurement, according to various aspects of the disclosure.

FIG. 6A illustrates a conceptual graph depicting output signal against reverse bias, and when a constant laser current is supplied to a laser diode, according to various aspects of the disclosure.

FIG. 6B illustrates a conceptual graph depicting normalized output signal against temperature, and when a constant laser current is supplied to a laser diode, according to various aspects of the disclosure.

FIG. 7 illustrates a block diagram showing a waveguide, a laser diode, a disk, and a slider of a data storage device, according to various aspects of the present disclosure.

FIG. 8 illustrates a conceptual graph depicting output signal against temperature, according to various aspects of the disclosure.

FIG. 9 illustrates a conceptual graph depicting laser current against temperature, according to various aspects of the disclosure.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

The embodiments described below are not intended to limit the disclosure to the precise form disclosed, nor are they intended to be exhaustive. Rather, the embodiment is presented to provide a description so that others skilled in the art may utilize its teachings. Technology continues to develop, and elements of the described and disclosed embodiments may be replaced by improved and enhanced items, however the teaching of the present disclosure inherently discloses elements used in embodiments incorporating technology available at the time of this disclosure.

A HAMR drive uses a laser diode (LD) to heat the media to aid in the recording process. For instance, during write operations, a forward bias power is applied to the LD. The amount of forward bias power applied is based at least in part on a steady state temperature associated with the write operation. Due to inefficiencies of electric to optical power, the laser diode also heats itself during lasing. In some cases, the LD cavity comprising the LD also heats up upon application of the forward bias power. In some circumstances, components (writer, reader, heat elements) in the slider also dissipate heat and the heat is conducted to the laser diode as the LD sub mount is mounted on the slider. These components (including the laser diode) may experience significant heating due to light absorption and electric-to-optical conversion inefficiencies as energy produced by the laser diode is delivered to the magnetic recording medium (e.g., disk surface). During a write operation, these light absorption and inefficiencies may cause the junction temperature of the LD to vary, which in turn may cause a shift in laser emission wavelength, leading to a change of optical feedback from optical path in the slider to the cavity of the laser diode, a phenomenon that is known to lead to mode hopping/power instability of the laser diode. In some circumstances, mode hopping is particularly problematic for lasers (or laser diodes) utilized in HAMR drives, as mode hopping can adversely impact HAMR drive performance. In some instances, a laser may operate in one resonator mode (e.g., emit light having a first wavelength) for some time, but then suddenly switch to another mode (e.g., emit light with a second wavelength, where the emitted light may have a different magnitude than the light emitted at the first wavelength) herein referred to as “mode hopping.” In some cases, a temperature change of the laser diode may result in mode hopping.

In some cases, a HAMR head (also referred to as a magnetic recording head) of a disk drive may be affected by one or more heat sources. Some non-limiting examples of such heat sources include one or more of a heater associated with a thermal fly-height control (TFC) element or slider, a writer coil, a near field transducer (NFT), a reader or reading element, and the laser diode. From an electrical standpoint, laser diodes are relatively inefficient devices. In some cases, the dissipated heat may lead to an increase in laser diode temperature. Furthermore, mode hops can result when the laser diode temperature changes (e.g., increases). As noted above, mode hops may refer to instances where there is a discrete change in optical power output by the laser diode. Mode hops may contribute to disturbances in the media temperature, which can adversely affect HAMR recording performance.

In some cases, the output of a laser diode, such as those used in heat assisted magnetic recording (HAMR) drivers, is dependent on a multitude of factors. Some non-limiting examples of factors include the mode in which the laser diode operates in a steady state condition, the temperature of the laser diode, the ambient temperature surrounding the laser diode (or the temperature in which the laser diode operates), and/or the laser current supplied to the laser diode. In some cases, the laser diode temperature can change significantly during operation. For instance, the laser diode temperature may be affected by self-heating induced in the laser diode (e.g., laser diode may heat up when it is reverse biased, when it is forward biased and in a lasing state, etc.), temperature increase of thermal fly height control (TFC) element, writer element, ambient temperature, etc. Since the laser output (e.g., wavelength, frequency, optical power output of the laser diode when it is ON or in a lasing state) is dependent on laser current and laser diode temperature, laser diodes often experience abrupt changes in laser output as the temperature changes. In some circumstances, on the fly measurement of laser optical output at different temperatures may be employed to help maintain a constant output power from the laser. This can help enhance disk drive operations by allowing the optical output power from the laser diode to be kept substantially constant across a range of temperatures and for different modes.

In some cases, laser diodes in Heat Assisted Magnetic Recording (HAMR) drives are susceptible to temperature-induced mode hopping, for instance, during the start of a write operation, track-to-track seek operation, and/or while a magnetic recording head is seeking over sector IDs (SIDs), to name a few non-limiting examples. During HAMR write, the temperature of a laser diode may increase (e.g., by 5-20 degrees C.), and several mode hop critical temperatures may be crossed during this temperature transient. In some circumstances, one or more mode hop events may be triggered during this transient phase, which may adversely impact write performance. For example, mode hop events during a HAMR write operation may result in non-uniformities in recording, which degrades HAMR recording performance. In some circumstances, optical power output of the laser diode may also vary during normal operation of the disk drive, e.g., when writing data to the disk. As such, accurate knowledge of the optical output of the laser diode for different temperatures and/or laser currents can facilitate in enhancing disk drive performance by reducing or minimizing variations in laser power output. In some embodiments, laser current feedback can be employed to help maintain a substantially constant laser power output, further described below.

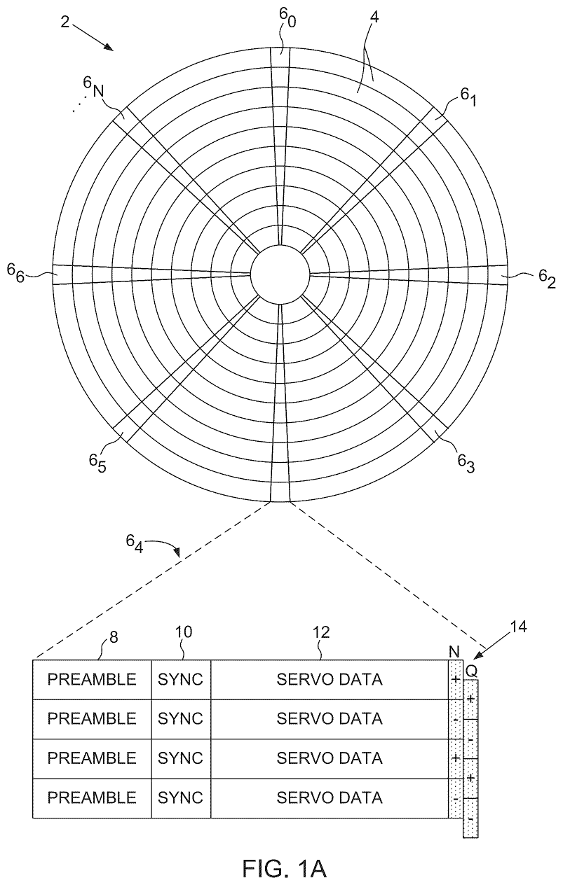

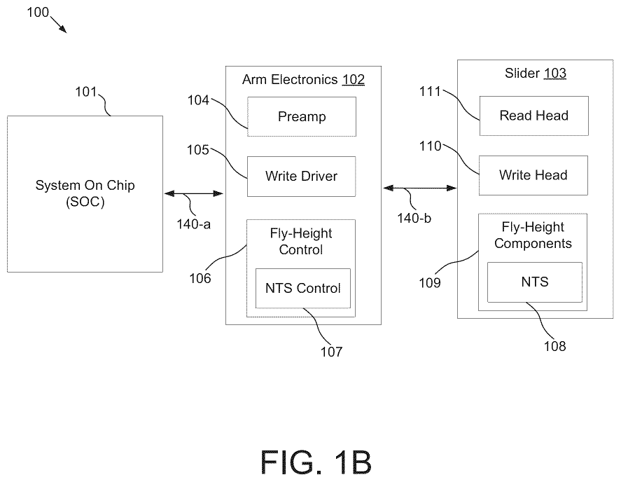

Turning now to FIG. 1B, which shows a block diagram illustration of selected components of a disk drive 100, according to various aspects of the present disclosure. As a disk rotates under a slider of a hard disk drive (HDD), the slider 103 is said to “fly” above the disk. In some cases, a thermal fly-height control (TFC) device (e.g., heater element) can be disposed within a slider (e.g., slider 103) to contort the slider near the read and write transducers (or elements), which lowers the fly-height for the read and write transducers. In some examples, read and write elements or transducers reside in the slider of an HDD. In some cases, the disk drive 100 may comprise fly-height control circuitry 106 that interfaces with fly-height components in the slider. Thermal fly-height control (TFC) is one prior art control technique that uses a heater element (not shown) disposed in the slider 103. The fly-height can be adjusted by heating the slider 103 with the heater. Electrical current supplied to the heater by fly-height control circuitry 106 generates heat to thermally expand the slider and modulate the fly-height. The fly-height components 109 can also include other elements in addition to the heater. In some cases, the relative temperature at an air bearing surface (ABS) may be used to estimate the resistance, R_{RTD}, of a resistive thermal detector (RTD), such as an embedded contact sensor (ECS) or a nearfield temperature sensor (NTS). Typically, the resistance of a material can be represented as a function of its intrinsic resistance and its dimensions (e.g., length, width, thickness or height). A fly-height control system can also include nearfield temperature sensors (NTS) 108 in the slider along the associated NTS control circuitry 107 in the arm electronics (AE) 102.

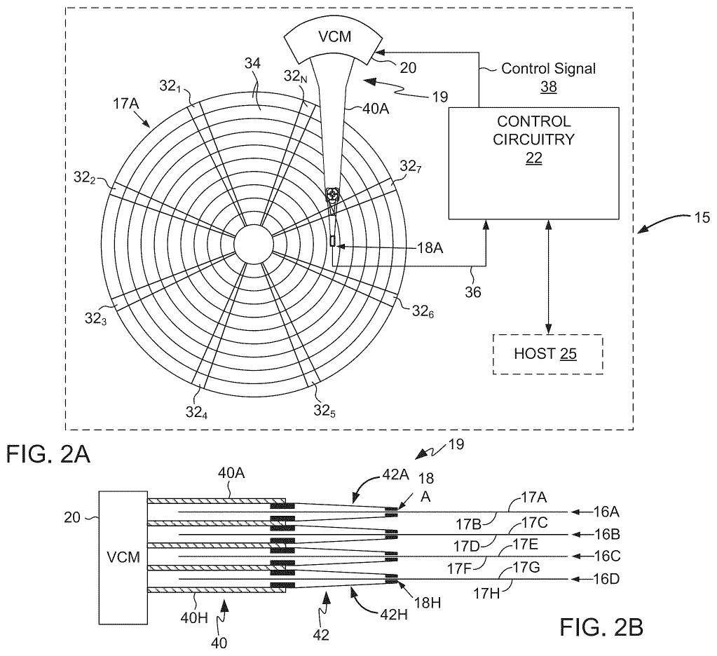

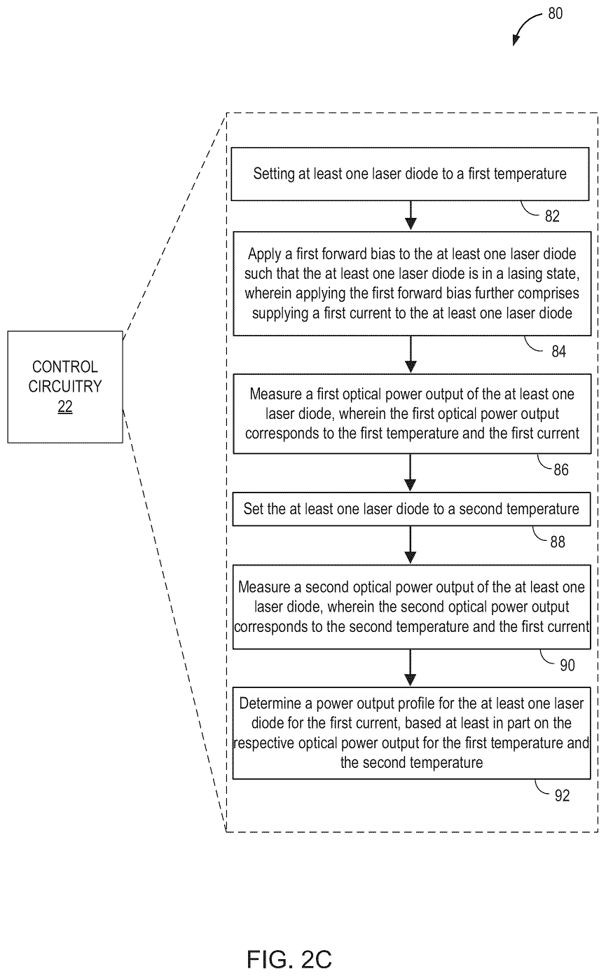

A disk drive 100 according to various aspects of the disclosure, as seen in FIG. 1B, comprises a system on a chip (SoC) 101, where the SoC 101 comprises the electronics and firmware for the drive and is used to control the functions of the drive including providing power and/or control signals to the components shown in AE chip 102. Each disk (shown as disks 16A-D in FIG. 2B) can have thin film magnetic material on each of the planar surfaces. Each recording surface may comprise a dedicated pair of read and write heads packaged in a slider 103 that is mechanically positioned over the rotating disk by an actuator (e.g., shown as actuator assembly 19 in FIG. 2B). In some examples, the actuator(s) also provide the electrical connections to the slider 103 components. The actuator assembly 19 may also comprise the arm electronics (AE) chip 102, the AE 102 comprising preamps 104 (e.g., read or write preamp) for the magnetic recording heads (e.g., read head 111, write head 110), write driver 105, and fly-height control circuitry 106. In some examples, the fly-height control circuitry 106 includes an NTS control circuit 107, for example, when the disk drive employs heat assisted magnetic recording (HAMR). It is noted that some of the components shown in AE 102 can be implemented or partially implemented in SoC 101 according to various aspects of the disclosure.

As seen, a first connection (e.g., flex cable) 140-a connects the SoC 101 to the AE 102, while a second connection (e.g., flex cable) 140-b connects the AE 102 to the slider 103. The AE 102 typically includes digital and analog circuitry for controlling the signals sent to components in the slider 103 and processing the signals received from the slider 103 components. The AE 102 can include registers that are set using serial data from the SoC 101 to provide parameters for the AE functions. The write driver 105 may generate an analog signal that is applied to an inductive coil in the write head 110 to write data by selectively magnetizing portions of the magnetic material on the surface of the rotating disk(s) 16.

As seen, slider 103 includes write head 110 configured to write data to a disk, a read head 111 configured to read data from the disk, fly-height components 109 configured to adjust slider fly-height (as described above) and resistive temperature detector (RTD), such as NTS 108, for sensing the temperature near the air-bearing surface (ABS). It is noted that ABS is generally used to describe the surface of the slider facing the disk, where the disk drive could be filled with gases other than air (e.g., gases containing helium, hydrogen, to name two non-limiting examples) and that the use of the “ABS” term to describe various aspects of the disclosure is not intended to limit the disclosure to air filled drives. In some cases, the NTS 108 is located proximate to the ABS and write head 110 (or alternatively the read head 111). The NTS 108 facilitates detecting a temperature generated by the slider's proximity to the disk or media. In various embodiments, the NTS 108 may comprise a thermal strip (e.g., metallic or semiconductor strip) on the slider 103.

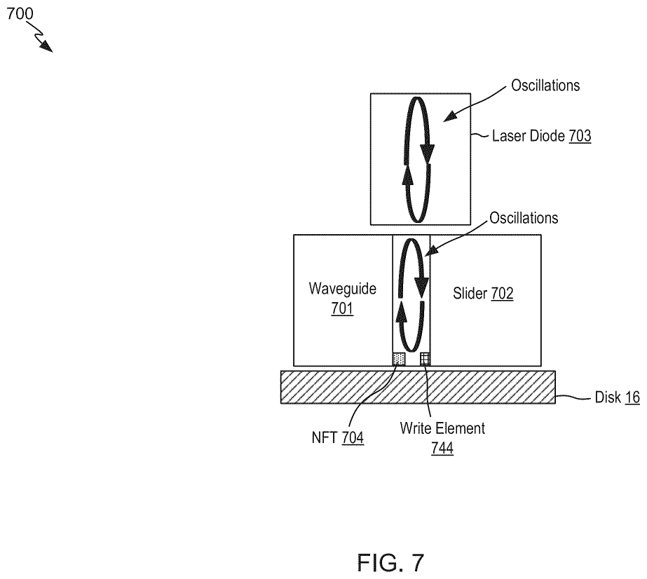

In some cases, a HAMR recording head (e.g., write head 110) also comprises optical components that direct light from a laser (or laser diode) to the disk. During recording, a write element applies a magnetic field to a heated portion of the storage medium or disk, where the heat lowers the magnetic coercivity of the media, allowing the applied field to change the magnetic orientation of the heated portion. The magnetic orientation of the heated portion determines whether a ‘1’ or a ‘0’ is recorded. Thus, by varying the magnetic field applied to the magnetic recording medium while it is moving, data can be encoded onto the medium. In some cases, a HAMR drive uses a laser diode (e.g., laser diode 703 in FIG. 7) to heat the media to aid in the recording process. In some cases, the LD is disposed within an LD cavity and is proximate to a HAMR read/write element (e.g., read/write element 744), where the read/write element has one end on the ABS of the slider 103 (also shown as slider 702 in FIG. 7). The ABS faces and is held proximate to a moving media surface during operation of the HDD.

In some cases, a HAMR drive may include a plurality of laser diodes and a plurality of magnetic recording heads, each magnetic recording head corresponding to one of the plurality of laser diodes. Furthermore, each magnetic recording head-laser diode pair may not be identical, for instance, with respect to their optical power output response over temperature. In addition to laser current and laser diode temperature, the optical power output of a laser diode may also depend on the particular head that it is utilized with.

Turning now to FIGS. 2A and 2B, which illustrate conceptual block diagrams of a top view and a side view of a data storage device in the form of a disk drive 15, in accordance with aspects of the present disclosure. Disk drive 15 comprises control circuitry 22, an actuator assembly 19, and a plurality of hard disks 16A, 16B, 16C, 16D (“hard disks 16,” “disks 16”). FIG. 2C depicts a flowchart for an example method 80 that control circuitry 22 of disk drive 15 may perform or execute in controlling the operations of disk drive 15, including the operations of heads 18 (e.g., heads 18A-18H) disposed on actuator assembly 19, in accordance with aspects of the present disclosure, as further described below. Actuator assembly 19 thus comprises heads 18 and is configured to position the one or more heads 18 over disk surfaces 17 of the one or more disks 16. Heads 18 may each comprise write and read elements, configured for writing and reading control features and data to and from a corresponding disk surface 17 of hard disks 16.

Actuator assembly 19 comprises a primary actuator 20 (e.g., a voice coil motor (“VCM”)) and a number of actuator arms 40 (e.g., topmost actuator arm 40A, as seen in the perspective view of FIGS. 2A and 2B). Each of actuator arms 40 comprises a head 18 at a distal end thereof (e.g., example head 18A comprised in topmost actuator arm 40A, in the view of FIGS. 2A and 2B). Each of actuator arms 40 is configured to suspend one of heads 18 in close proximity over a corresponding disk surface 17 (e.g., head 18A suspended by topmost actuator arm 40A over topmost corresponding disk surface 17A, head 18H suspended by lowest actuator arm 40H over lowest corresponding disk surface 17H). Various examples may include any of a wide variety of other numbers of hard disks and disk surfaces, other numbers of actuator arm assemblies and primary actuators besides the one actuator assembly 19 and the one primary actuator 20 in the example of FIGS. 2A and 2B, and other numbers of fine actuators on each actuator arm, for example.

FIG. 2A also depicts servo sectors 32 (e.g., servo sectors 321 through 32N) written onto disk surfaces 17. In some cases, when manufacturing a disk drive, servo sectors 32 may be written to disk surfaces 17 to define a plurality of evenly-spaced, concentric tracks 34. As an example, each servo sector 32 may include a phase lock loop (PLL) field, a servo sync mark (SSM) field, a track identification (TKID) field, a sector ID, and a group of servo bursts (e.g., an alternating pattern of magnetic transitions) that the servo system of the disk drive samples to align the moveable transducer head (e.g., disk head 18) with and relative to, a particular track 34. Each circumferential track 34 includes a plurality of embedded servo sectors 32 utilized in seeking and track following. The plurality of servo sectors 32 are spaced sequentially around the circumference of a circumferential track 34 and extend radially outward from the inner diameter (ID) of disk surface 17. These embedded servo sectors 32 contain servo information utilized in seeking and track following and are interspersed between data regions on disk surfaces 17. Data is conventionally written in the data regions in a plurality of discrete data sectors. Each data region is typically preceded by a servo sector 32. Host 25 may be a computing device such as a desktop computer, a laptop, a server, a mobile computing device (e.g., smartphone, tablet, Netbook, to name a few non-limiting examples), or any other applicable computing device. Alternatively, host 25 may be a test computer that performs calibration and testing functions as part of the disk drive manufacturing processing.

In some examples, the control circuitry 22 is configured to control the actuation of the primary actuator (i.e., VCM). Further, the VCM is configured to actuate the head 18 over the disk surfaces 17. In some examples (80), the control circuitry 22 is also configured to set at least one laser diode of the data storage device to a first temperature (82); apply a first forward bias to the at least one laser diode such that the at least one laser diode is in a lasing state, wherein applying the first forward bias further comprises supplying a first current to the at least one laser diode (84); measure a first optical power output of the at least one laser diode, wherein the first optical power output corresponds to the first temperature and the first current (86); set the at least one laser diode to a second temperature (88); measure a second optical power output of the at least one laser diode, wherein the second optical power output corresponds to the second temperature and the first current (90); and determine a power output profile for the at least one laser diode for the first current, based at least in part on the respective optical power output for the first temperature and the second temperature (92).

In some embodiments, setting the at least one laser diode to the first temperature comprises applying a first reverse bias for a certain duration (e.g., at least 0.1 seconds, at least 0.2 seconds, at least 0.5 seconds, etc.), which helps preheat the laser diode to the first steady state temperature during LD fingerprint measurement (i.e., power output profile measurement). Similarly, setting the at least one laser diode to the second temperature comprises applying a second reverse bias for a certain duration (e.g., at least 0.1 seconds), which helps preheat the laser diode to the second steady state temperature during LD fingerprint measurement. In some cases, the laser diode is positioned inside a laser diode cavity and the forward bias is applied using a preamplifier. Additionally, and as described in further detail below, determining a LD fingerprint profile for each laser diode (or magnetic recording head-laser diode pair) facilitates implementation of a laser current feedback loop to help maintain a substantially constant laser power output across a range of temperatures.

In the embodiment of FIG. 2A, the control circuitry 22 may also process a read signal 36 emanating from the head 18_{A} to demodulate servo data written on the disk (e.g., servo sectors 32) to generate a position error signal (PES) representing an error between the actual position of the head and a target position relative to a target track. The control circuitry 22 may process the PES using a suitable servo control system to generate the control signal 38 (e.g., a VCM control signal) applied to the VCM 20 which rotates an actuator arm 40 about a pivot in order to actuate the head 18 radially over the disk surface 17 in a direction that reduces the PES. In one embodiment, the disk drive may also comprise a suitable microactuator, such as a suitable piezoelectric (PZT) element for actuating the head 18 relative to a suspension, or for actuating a suspension relative to the actuator arm 40.

In one embodiment, the servo data (e.g., servo sectors 32) read from the disk surface 17, i.e., in order to servo the head over the disk during access operations, may be self-written to the disk using the control circuitry 22 internal to the disk drive. In some examples, a plurality of spiral servo tracks are first written to the disk surface 17, and then servo sectors 32 are written to the disk while servoing on the spiral servo tracks. In order to write the spiral servo tracks to the disk surface 17, at least one bootstrap spiral track is first written to the disk without using position feedback from servo data (i.e., the actuator or VCM 20 is controlled open loop with respect to servo data on the disk). Before writing the bootstrap spiral track, feedforward compensation is generated by evaluating the BEMF voltage generated by the VCM 20 during a calibration seek (where the BEMF voltage represents an estimated velocity of the VCM). The bootstrap spiral track is then written to the disk using the feed-forward compensation. In some embodiments, the BEMF voltage representing the velocity of the VCM 20 may be sampled at any suitable sample rate in order to update the feed-forward compensation at any suitable frequency during seek operations.

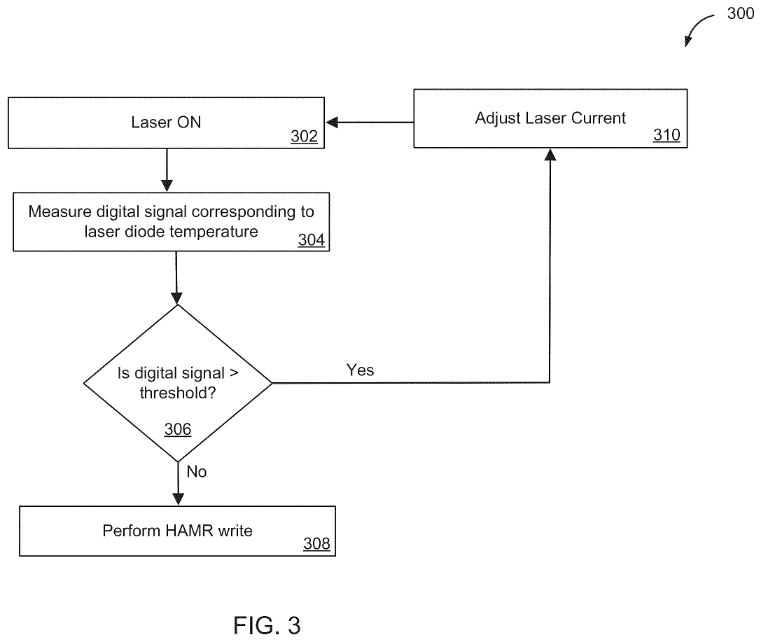

FIG. 3 illustrates an example of a method 300 for steady state laser diode fingerprint measurement and compensation, according to various aspects of the disclosure. In some cases, the method 300 may be implemented using one or more of the control circuitry 22, the SoC 101, and/or the preamp 104. The method 300 described below is generally directed to utilizing the laser diode fingerprint information for resolving issues related to variations in laser power when the temperature changes. Specifically, but without limitation, method 300 provides a technique for helping maintain the optical output response/power from a laser diode at a substantially constant level across different temperatures, based at least in part on adjusting the laser current. In some cases, adjusting the laser current is further based on the laser diode fingerprint information.

As seen, a first operation 302 comprises applying a forward bias to the laser diode to turn ON the laser (or laser diode). Next, a second operation 304 comprises measuring a signal (e.g., digital signal) corresponding to at least one of the NFT Temperature Sensor (NTS), Embedded Contact Sensor (ECS), laser diode temperature, and thermistor of the disk drive.

At decision block 306, the method 300 comprises determining if the signal is greater than a corresponding threshold. For example, if the digital signal measured at operation 304 corresponds to the NTS, the control circuitry 22 determines if the NTS digital signal is greater than a NTS threshold at block 306. Similarly, if the digital signal measured at operation 304 corresponds to the laser diode temperature, the control circuitry 22 determines if the LD temperature exceeds a corresponding LD temperature threshold at block 306.

If yes, the method 300 proceeds to operation 310, where operation 310 comprises adjusting the laser current supplied to the laser diode. In some cases, adjusting the laser current is based at least in part on accessing a lookup table (or another similar data structure), where the lookup table comprises a relationship between the optical power output, the laser current, and the temperature. In accordance with aspects of the present disclosure, the laser current can be adjusted to help maintain the optical power output at a substantially constant level, since the optical power output of the laser diode is linked to the laser current and the temperature.

If the digital signal is lower than the threshold (i.e., output of decision block 306 is ‘No’), the method 300 proceeds to operation 308, where operation 308 comprises performing a HAMR write on at least one disk of the disk drive.

In some aspects, the steady state laser diode fingerprint measurement and compensation disclosed herein can facilitate in reducing or minimizing adverse effects of mode hops (i.e., when the optical power output of the laser diode changes due to a change in temperature) by (1) creating a mapping of the optical power output to the laser diode temperature and/or laser current and (2) adjusting one or more the laser diode temperature and/or the laser current based on the mapping. Furthermore, by creating a calibration or lookup table (e.g., during the disk drive manufacturing process) for each magnetic recording head-laser diode pair, aspects of the disclosure allow real-time adjustment of one or more parameters (e.g., laser current and/or laser diode temperature) during operation of the disk drive, which helps ensure a stable/constant optical output from the laser.

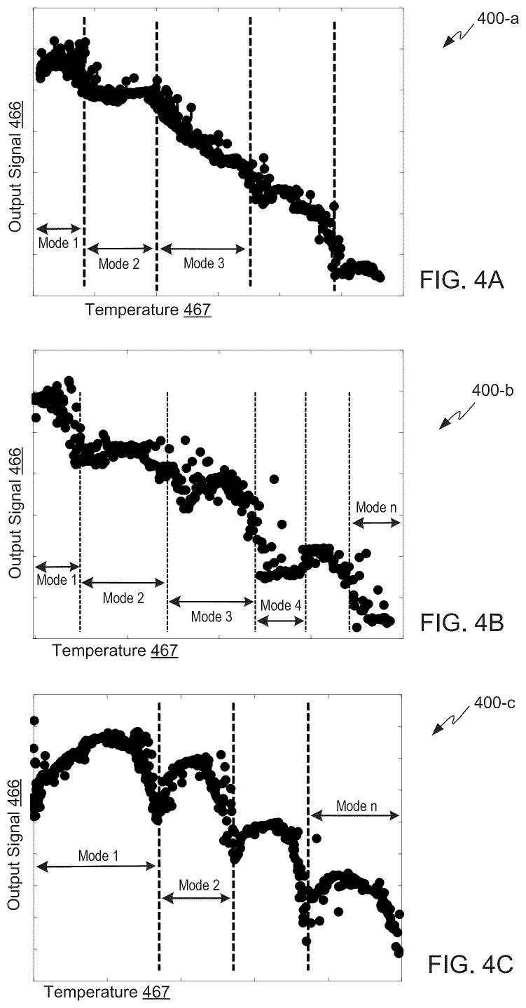

FIGS. 4A-4C illustrate conceptual graphs 400-a, 400-b, and 400-c, respectively, showing output signal 466 against temperature 467 for three laser diodes of a data storage device, according to various aspects of the disclosure. In some cases, the temperature 467 shown along the x-axis may correspond to the laser diode temperature. Alternatively, in some implementations, the temperature 467 can be derived from signals measured using a NTS, ECS, or a thermistor of the disk drive. In this example, each laser diode is associated with a different magnetic recording head of the data storage device. In some cases, the output signal 466 shown along the y-axis may correspond to an output power output of a laser diode, for instance, measured using a photodiode (PD). The PD outputs a voltage, where the voltage depends on the intensity of the incoming light from the laser diode. It should be noted that a photodiode is only one example of a light sensor that can be employed to monitor laser power (or optical power) from a laser diode. That is, other types of light sensors besides PDs are contemplated in different embodiments and the examples listed herein are not intended to limit the scope or spirit of the disclosure. In some other cases, the output signal 466 may be based in part on measuring a recording signature on the media.

Broadly, the graphs 400-a through 400-c relate to mode hop fingerprint measurement for laser diode(s) in a steady state condition (i.e., laser current is constant). Some aspects of the present disclosure are directed to a technique for characterizing the laser in each magnetic recording head in the HAMR drive in the steady state to generate a fingerprint profile (e.g., power output profile) for that laser. In some examples, characterizing the fingerprint profile of the laser diode comprises preheating the laser (e.g., by applying a reverse bias to the laser diode, using an extrinsic heater or antiparallel diode on the laser diode or using the laser diode itself or resistive heater on the laser diode) and then measuring the response of the LD at a working laser current condition (e.g., laser current that may be used during a write operation), further described below.

In the examples shown in FIGS. 4A-C, the laser diode current is kept constant and the output signal (e.g., optical power output from the laser diode) is measured for different temperatures. For instance, the temperature may be swept from around 20 degrees Celsius to around 50 degrees Celsius and the output can be measured across the range of temperatures. As seen, on average, the optical power output of the laser diode(s) drop when the temperature is increased (e.g., increased from ambient temperature, such as 20-25 degrees Celsius, to a higher temperature, such as 40-50 degrees Celsius). FIGS. 4A-C also depict the different modes (e.g., mode 1, mode 2, mode n) for each laser diode and the variations seen in the responses for different magnetic recording head-laser diode pairs. In some cases, a laser diode fingerprint may be measured by monitoring the laser diode response (e.g., measured using a photodiode or another applicable light sensor) for different laser currents, different temperatures, or a combination thereof. In some embodiments, a laser diode fingerprint can be determined for each magnetic recording head-laser diode pair. As seen, for instance in graph 400-b, the optical power output is generally constant for a particular mode (e.g., mode 2, mode 4) but varies significantly between different modes (e.g., mode 3 vs mode 4).

In accordance with aspects of the present disclosure, the laser diode, such as laser diode 703 in FIG. 7, of a data storage device may be preheated to a target or steady-state temperature (e.g., a temperature associated with a write operation). In some cases, pre-heating the laser diode may comprise applying a reverse bias to the laser diode for a sufficient duration that allows the temperature of the laser diode to be at or near the target temperature. Once the laser diode is preheated, the control circuitry or a preamplifier may cease applying the reverse bias and transition to applying a forward bias to the laser diode. In some cases, the optical response of the laser diode can be measured for a constant laser current and when the laser diode is forward biased (i.e., in a lasing state). It should be noted that, the use of a reverse bias to preheat the laser diode is not intended to be limiting and other techniques for preheating the laser diode for performing steady state LD fingerprint measurements are contemplated in different embodiments. In one non-limiting example, an extrinsic heater, such as an antiparallel diode, on the laser diode may be utilized to pre-heat the laser diode.

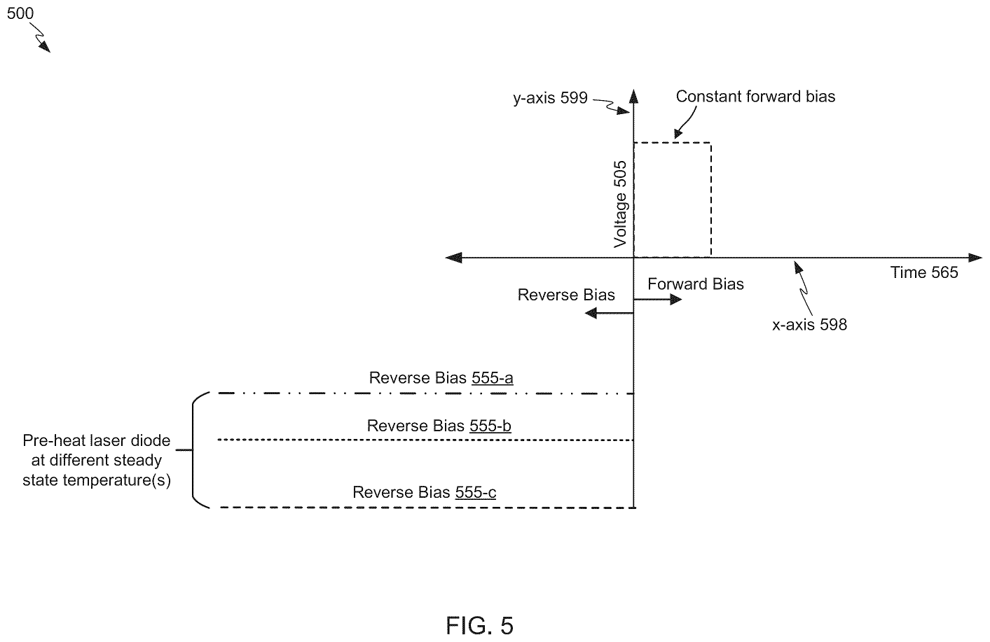

Thus, in accordance with aspects of the disclosure, the fingerprint profile of the laser diode can be characterized by (1) preheating the laser diode, and (2) measuring the laser output as a function of laser temperature when the laser diode is in a forward bias condition. In some embodiments, the optical response of the laser diode, e.g., measured using a PD, may be determined for different temperatures and/or for different laser currents. For example, as depicted in FIG. 5, the laser diode may be preheated using different reverse bias levels. Since different reverse bias levels correspond to different LD temperatures (i.e., steady state temperatures), aspects of the present disclosure allow determining a relation between the optical power output of the laser diode and the LD temperature for a given laser current.

FIG. 5 illustrates a conceptual graph 500 showing voltage 505 (on the vertical or y-axis 599) against time 565 (on the horizontal or x-axis 598) as it relates to fingerprint measurement for a laser diode (e.g., laser diode or LD 703 in FIG. 7) in the steady state, according to various aspects of the disclosure. In this example, a laser diode of a data storage device is preheated to different steady state temperatures using different reverse biases (e.g., first reverse bias level 555-a, second reverse bias level 555-b, third reverse bias level 555-c). In some aspects, each reverse bias level 555 is associated with a different steady state temperature of the laser diode. In this way, the steady state temperature of the LD can be changed by adjusting the reverse bias level 555 applied to the laser diode. Once the laser diode is preheated (e.g., to a first temperature associated with reverse bias level 555-a), the LD response (e.g., optical output) can be measured for a constant forward bias, as shown in FIG. 5. As noted above, in some embodiments, characterization of the power output profile (or fingerprint profile) of the LD involves sweeping across different temperatures and measuring the corresponding LD response (i.e., when the LD is in a forward bias condition and laser current is constant). This process can be repeated by changing the reverse bias level (i.e., to effectuate a change in the LD temperature) and remeasuring the LD response. In other words, a sweep of the temperature range would mean that the cycle of FIG. 5 is repeated many times on the time scale 565 to generate the complete characterization. The same principle of temperature setting and measuring would apply for other methods of setting the LD temperature such as via resistive heating, etc.

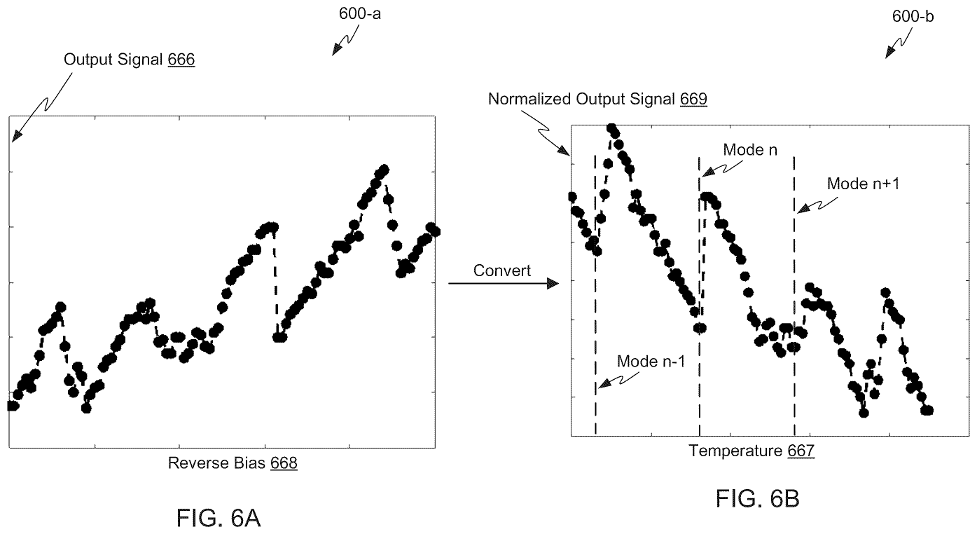

FIG. 6A illustrates a conceptual graph 600-a showing output signal 666 of a laser diode against reverse bias 668, and when a constant laser current is supplied to the laser diode, according to various aspects of the disclosure. Here, the reverse bias 668 shown on the horizontal axis corresponds to the reverse bias applied to preheat the laser diode to a particular steady state temperature, as described above in relation to FIG. 5. Furthermore, the output signal 666 on the vertical axis corresponds to the optical power output of the laser diode measured using a photodiode (or another applicable light sensor and/or other output measurement methods noted above).

FIG. 6B illustrates a conceptual graph 600-b showing normalized output signal 669 against temperature 667, and when a constant laser current is supplied to the laser diode, according to various aspects of the disclosure. In this example, the reverse bias 668 shown in FIG. 6A is converted to an equivalent temperature, based on determining the relationship of the reverse bias to the LD steady state temperature. As seen, on average, the normalized optical signal 669 of the laser diode (i.e., when it is forward biased and driven using a constant laser current) drops as the temperature increases. However, the drop in laser optical power is not linear. Instead, numerous ripples are seen (i.e., due to the different modes n−1, n, n+1, etc.). In some circumstances, these ripples are a result of mode hops that are encountered when the LD temperature changes.

Thus, FIGS. 6A-6B depict the output profile measurement (or fingerprint

measurement) for a laser diode for a given laser current and across a range of temperatures, where the output profile measurement is performed by preheating the laser diode using different levels of reverse bias (i.e., corresponding to different LD steady state temperatures) and monitoring the corresponding LD optical response. In some cases, the output or fingerprint profile measurement technique described in relation to FIGS. 5, 6A, and/or 6B may be repeated for different laser currents, which allows a lookup table (or another applicable data structure) to be created, where the lookup table comprises a relationship between the LD optical power output, temperature and/or reverse bias, and laser current. In some instances, the LD fingerprint profile characterization technique described above can be repeated for each head-laser diode pair.

Some aspects of the present disclosure are also directed to a technique for maintaining a substantially constant laser power output via laser current feedback, as described above in relation to FIG. 3. For instance, the information gathered from the LD fingerprint profile characterization can be utilized in a feedback loop to help maintain a substantially constant laser output across temperature during disk drive operation. In some embodiments, the laser current (i.e., current used to drive the laser diode when it is forward biased) can be adjusted on the fly to help maintain a constant laser power output even though the LD temperature is varying.

FIG. 7 illustrates a block diagram 700 showing a waveguide (WG) 701, a laser diode (LD) 703, a disk 16, a near field transducer (NFT) 704, and a slider 702 of a data storage device, according to various aspects of the present disclosure. As seen, the WG 701 and the NFT 704 are located proximate a write element 744 to provide local heating of the media (i.e., disk 16) during write operations. In some cases, the LD 703 produces optical energy (e.g., having a wavelength between 700-900 nm), which is delivered to the magnetic recording medium or disk 16. In some examples, the LD 703 may be preheated prior to the start of a write operation by applying a reverse bias (or negative voltage) to the LD 703. The LD 703 may not emit laser light while the reverse bias is applied. In such cases, no data writing, rewriting, and/or erasure occurs. In this way, the LD cavity in which the LD 703 is positioned is preheated when the reverse bias is applied to the LD 703. To begin writing (or rewriting) data on the disk 16, the bias applied to the LD 703 is switched from a reverse bias to a forward bias. In some cases, the temperature of the LD 703 is configured to stay the same or substantially the same when the bias is switched to the forward bias, which serves to minimize the temperature transients, as compared to the prior art. In some aspects, reverse biasing of the LD 703 to preheat it before commencing the write operation (or alternatively, to maintain the LD temperature at the steady-state temperature during certain disk drive operations such as track-to-track seek, seeking over sector IDs) facilitates enhanced control of the LD steady-state temperature, which helps avoid mode hops related to temperature transients. In some cases, the LD 703 is maintained in the pre-heat state before actually starting the write operation, which helps minimize or reduce laser-on transition time.

The LD (shown as laser diode 703 in FIG. 7) provides optical-based energy to heat the media surface, e.g., at a point near the read/write element 744. In some cases, optical path components, such as a waveguide 701, are formed integrally within the slider 702 to deliver light from the laser diode 703 to the media. In some circumstances, various components (e.g., write element 744, NFT 704, LD 703, etc.) experience significant heating due to light absorption and inefficiencies in electrical-to-optical energy conversion as energy produced by the LD 703 is delivered to the magnetic recording medium or disk 16. In some cases, temperature variations (e.g., during normal operations of a disk drive) can lead to variations in optical power output of the LD. For example, temperature variations of the LD can lead to a change of optical feedback from the optical path in the slider 702 to the LD cavity, resulting in mode hopping (i.e., power instability) of the LD 703. Mode hopping can degrade performance of HAMR drives, as mode hopping leads to shifting/jumping of laser output power and magnetic transition shifting between data blocks. Large transition shifts in data blocks may increase errors, degrading disk drive performance.

In some embodiments, a fingerprint profile of a LD can be characterized by pre-heating the LD to different temperatures using different reverse biases and measuring the LD response for each of those temperatures (i.e., temperature associated with a respective reverse bias). In some embodiments, the control circuitry 22 sweeps through different reverse biases and measures the LD response (i.e., when the LD is in the forward bias condition) for a given laser current to characterize the laser diode for that current. The control circuitry 22 may repeat this process by sweeping through different laser currents and measuring the corresponding LD fingerprint for the different laser currents.

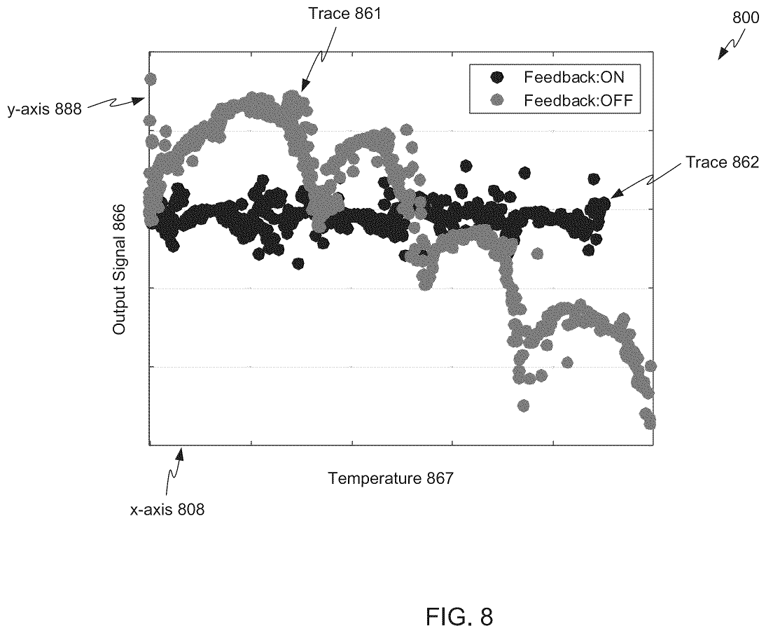

FIG. 8 illustrates a conceptual graph 800 showing output signal 866 against temperature 867, according to various aspects of the disclosure. In some cases, the temperature 867 shown along the x-axis 808 may correspond to the laser diode temperature. Alternatively, in some implementations, the temperature 867 can be derived from signals measured using a NTS, ECS, or a thermistor. The output signal 866 shown along the y-axis 888 may correspond to an output power output of a laser diode, for instance, measured using a photodiode. It should be noted that a photodiode is only one example of a light sensor that can be employed to monitor laser power (or optical power) from a laser diode. That is, other types of light sensors besides PDs are contemplated in different embodiments and the examples listed herein are not intended to limit the scope or spirit of the disclosure.

In some instances, LD modes may be chosen so as to output substantially the same laser power at different temperatures. Additionally, or alternatively, laser current feedback may be employed for steady state laser power operation. FIG. 8 depicts two output signal traces, one where laser current feedback is not employed (trace 861) and another where laser current feedback is employed (trace 862). As seen, when laser current feedback is OFF, there are significant variations in the output signal as the temperature changes. However, when laser current feedback is ON, the output signal 866 stays relatively constant across a wide range of temperatures.

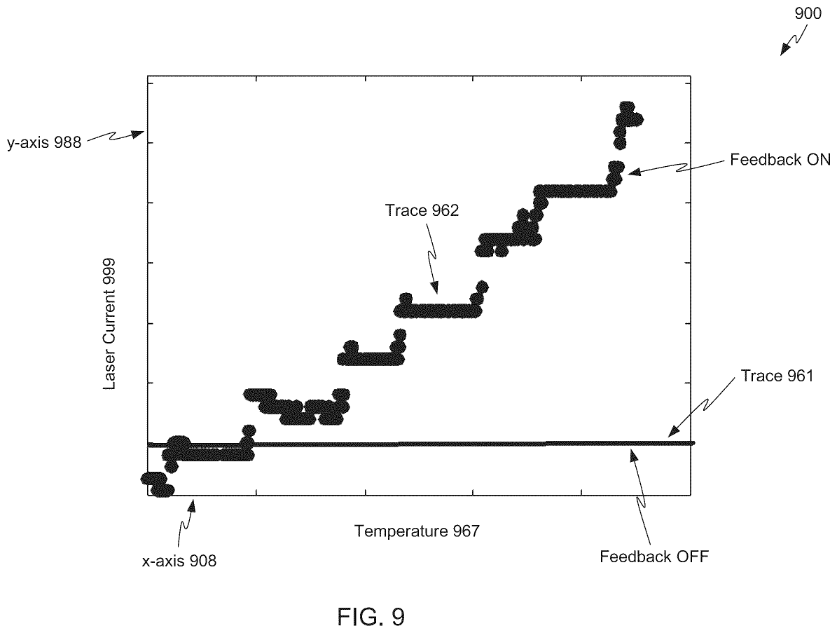

FIG. 9 illustrates a conceptual graph 900 showing laser current 999 (on the vertical or y-axis 988) against temperature 967 (on the horizontal or x-axis 908), according to various aspects of the disclosure. As seen, FIG. 9 shows a first trace 961 (laser current feedback is OFF) and a second trace 962 (laser current feedback is ON). When laser current feedback is OFF, the laser current 999 stays constant or substantially constant across different temperatures. Additionally, when laser current feedback is ON, the laser current generally increases with an increase in temperature. In some instances, the laser current increases in a staircase pattern, as shown in FIG. 9. In other cases, however, the laser current 999 may increase in a linear manner as the temperature 967 increases.

Any suitable control circuitry (e.g., control circuitry 22 in FIG. 2A) may be employed to implement the flow diagrams in the above examples, such as any suitable integrated circuit or circuits. For example, the control circuitry may be implemented within a read channel integrated circuit, or in a component separate from the read channel, such as a data storage controller, or certain operations described above may be performed by a read channel and others by a data storage controller. In one example, the read channel and data storage controller are implemented as separate integrated circuits, and in another example, they are fabricated into a single integrated circuit or system on a chip (SoC), such as SoC 101 in FIG. 1B. In addition, the control circuitry 22 may include a preamp circuit, such as preamplifier 104 in FIG. 1B, where the preamp circuit is implemented as a separate integrated circuit, integrated into the read channel or data storage controller circuit, or integrated into the SoC.

In some examples, the control circuitry, such as, but not limited to, control circuitry 22, comprises a microprocessor executing instructions, the instructions being operable to cause the microprocessor to perform the flow diagrams (e.g., shown in FIGS. 2C and 3) described herein. The instructions may be stored in any computer-readable medium. In some examples, they may be stored on a non-volatile semiconductor memory device, component, or system external to the microprocessor, or integrated with the microprocessor in an SoC. In some examples, the instructions are stored on the disk and read into a volatile semiconductor memory when the disk drive is powered on. In some examples, the control circuitry comprises suitable logic circuitry, such as state machine circuitry. In some examples, at least some of the flow diagram blocks may be implemented using analog circuitry (e.g., analog comparators, timers, etc.), and in other examples at least some of the blocks may be implemented using digital circuitry or a combination of analog and digital circuitry.

In various examples, one or more processing devices may comprise or constitute the control circuitry 22 as described herein, and/or may perform one or more of the functions of control circuitry as described herein. In various examples, the control circuitry 22, or other one or more processing devices performing one or more of the functions of control circuitry as described herein, may be abstracted away from being physically proximate to the disks and disk surfaces. The control circuitry, or other one or more processing devices performing one or more of the functions of control circuitry as described herein, may be part of or proximate to a rack of or a unitary product comprising multiple data storage devices, or may be part of or proximate to one or more physical or virtual servers, or may be part of or proximate to one or more local area networks or one or more storage area networks, or may be part of or proximate to a data center, or may be hosted in one or more cloud services, in various examples.

In various examples, a disk drive, such as disk drive 15, may include a magnetic disk drive, an optical disk drive, a hybrid disk drive, or other types of disk drive. In addition, some examples may include electronic devices such as computing devices, data server devices, media content storage devices, or other devices, components, or systems that may comprise the storage media and/or control circuitry as described above.

The various features and processes described above may be used independently of one another or may be combined in various ways. All possible combinations and subcombinations are intended to fall within the scope of this disclosure. In addition, certain method(s), event(s), or process blocks may be omitted in some implementations. The methods and processes described herein are also not limited to any particular sequence, and the blocks or states relating thereto can be performed in other sequences. For example, described tasks or events may be performed in an order other than that specifically disclosed, or multiple may be combined in a single block or state. The example tasks or events may be performed in serial, in parallel, or in another manner. Tasks or events may be added to or removed from the disclosed examples. The example systems and components described herein may be configured differently than described. For example, elements may be added to, removed from, or rearranged compared to the disclosed examples.

While certain example embodiments are described herein, these embodiments are presented by way of example only, and do not limit the scope of the disclosure. Thus, nothing in the foregoing description implies that any particular feature, characteristic, step, module, or block is necessary or indispensable. The novel methods and systems described herein may be embodied in a variety of other forms. Various omissions, substitutions and changes in the form of the methods and systems described herein may be made without departing from the spirit and scope of the present disclosure.

Method 80 and other methods (e.g., method 300) of this disclosure may include other steps or variations in various other embodiments. Some or all of any of method(s) 80 and/or 300 may be performed by or embodied in hardware, and/or performed or executed by a controller, a CPU, a field-programmable gate array (FPGA), a SoC, a multi-processor system on chip (MPSoC), which may include both a CPU and an FPGA, and other elements together in one integrated SoC, or other processing device or computing device processing executable instructions, in controlling other associated hardware, devices, systems, or products in executing, implementing, or embodying various subject matter of the method.

Data storage systems, devices, and methods are thus shown and described herein, in various foundational aspects and in various selected illustrative applications, architectures, techniques, and methods for steady state laser diode fingerprint measurement and compensation for data storage devices, such as HAMR drives, and other aspects of this disclosure. Persons skilled in the relevant fields of art will be well-equipped by this disclosure with an understanding and an informed reduction to practice of a wide panoply of further applications, architectures, techniques, and methods for steady state laser diode fingerprint measurement and compensation for data storage devices, such as HAMR drives, and other aspects of this disclosure encompassed by the present disclosure and by the claims set forth below.

As used herein, the recitation of “at least one of A, B and C” is intended to mean “either A, B, C or any combination of A, B and C.” The descriptions of the disclosed examples are provided to enable any person skilled in the relevant fields of art to understand how to make or use the subject matter of the present disclosure. Various modifications to these embodiments will be readily apparent to those skilled in the art based on the present disclosure, and the generic principles defined herein may be applied to other examples without departing from the spirit or scope of the disclosure. Thus, the present disclosure is not limited to the embodiments shown herein but is to be accorded the widest scope consistent with the principles and novel features disclosed herein.

The present disclosure and many of its attendant advantages will be understood by the foregoing description, and various changes may be made in the form, construction, and arrangement of the components without departing from the disclosed subject matter or without sacrificing all of its material advantages. The form described is merely explanatory, and the following claims encompass and include a wide range of embodiments, including a wide range of examples encompassing any such changes in the form, construction, and arrangement of the components as described herein.

While the present disclosure has been described with reference to various examples, it will be understood that these examples are illustrative and that the scope of the disclosure is not limited to them. All subject matter described herein are presented in the form of illustrative, non-limiting examples, and not as exclusive implementations, whether or not they are explicitly called out as examples as described. Many variations, modifications, and additions are possible within the scope of the examples of the disclosure. More generally, examples in accordance with the present disclosure have been described in the context of particular implementations. Functionality may be separated or combined in blocks differently in various examples of the disclosure or described with different terminology, without departing from the spirit and scope of the present disclosure and the following claims. These and other variations, modifications, additions, and improvements may fall within the scope of the disclosure as defined in the claims that follow.

What is claimed is:

1. A data storage device, comprising:
one or more disks;
an actuator arm assembly comprising one or more magnetic recording heads;
at least one laser diode; and
one or more processing devices configured to:
set the at least one laser diode to a first temperature;
apply a first forward bias to the at least one laser diode such that the at least one laser diode is in a lasing state, wherein applying the first forward bias further comprises supplying a first current to the at least one laser diode;
measure a first optical power output of the at least one laser diode, wherein the first optical power output corresponds to the first temperature and the first current;
set the at least one laser diode to a second temperature;
measure a second optical power output of the at least one laser diode, wherein the second optical power output corresponds to the second temperature and the first current; and
determine an output profile for the at least one laser diode, based at least in part on the respective optical power output at the first temperature and the second temperature.

2. The data storage device of claim 1, wherein the one or more processing devices are further configured to:
set the at least one laser diode to a third temperature; and
measure a third optical power output of the at least one laser diode, wherein the third optical power output corresponds to the third temperature and the first current;
wherein determining the output profile for the at least one laser diode is further based on the third optical power output at the third temperature.

3. The data storage device of claim 2, wherein determining the output profile for the at least one laser diode is based at least in part on sweeping the at least one laser diode through a plurality of temperatures and measuring a corresponding optical power output for each of the plurality of temperatures, including at least the first, the second, and the third temperatures, and wherein the output profile is specific to the first current.

4. The data storage device of claim 1, wherein:
setting the at least one laser diode to the first temperature comprises applying a first reverse bias to the at least one laser diode to preheat the at least one laser diode to the first temperature; and
setting the at least one laser diode to the second temperature comprises applying a second reverse bias to the at least one laser diode to preheat the at least one laser diode to the second temperature.

5. The data storage device of claim 4, wherein the one or more processing devices are further configured to:
preheat the at least one laser diode to the first temperature prior to applying the first forward bias; and
apply the first forward bias to the at least one laser diode, based at least in part on preheating the at least one laser diode to the second temperature and prior to measuring the second optical power output.

6. The data storage device of claim 1, wherein the one or more processing devices are further configured to:
determine one or more other output profiles for the at least one laser diode, based at least in part on sweeping the at least one laser diode through a plurality of temperatures and measuring a corresponding optical power output for each of the plurality of temperatures, wherein each of the one or more output profiles is associated with one or more of a different forward bias and a different current.

7. The data storage device of claim 6, wherein the one or more processing devices are further configured to:
select an optical power output for a write operation, wherein the write operation is associated with a steady state temperature;
initiate the write operation by,
activating a magnetic recording head corresponding to a first one of the at least one laser diode,
applying a forward bias to the first laser diode, and
supplying a first laser current to the first laser diode;
monitor an optical power output of the first laser diode; and
determine whether the optical power output of the first laser diode is different from the optical power output selected for the write operation.

8. The data storage device of claim 7, wherein the one or more processing devices are further configured to:
adjust the first laser current supplied to the first laser diode, based at least in part on determining the optical power output of the first laser diode is different from the optical power output selected for the write operation, and wherein the adjusting the first laser current is based at least in part on determining the one or more output profiles.

9. The data storage device of claim 8, wherein, prior to adjusting the first laser current supplied to the first laser diode, the one or more processing devices are further configured to:
identify, from the one or more output profiles, an output profile associated with the magnetic recording head and the first laser diode.

10. The data storage device of claim 9, wherein the one or more processing devices are further configured to:
adjust the first laser current to minimize or reduce variations in the optical power output of the first laser diode relative to the optical power output selected for the write operation.

11. The data storage device of claim 1, wherein setting the at least one laser diode comprises using at least one of an extrinsic heater and an antiparallel diode at or near the at least one laser diode to preheat the at least one diode to a respective one of the first temperature and the second temperature.

12. The data storage device of claim 11, wherein the at least one laser diode comprises a plurality of laser diodes and the one or more magnetic recording heads comprise a plurality of magnetic recording heads, each magnetic recording head corresponding to one of the plurality of laser diodes, and wherein the one or more processing devices are further configured to:
measure an optical power output for each pair of magnetic recording head and laser diode for a plurality of temperatures, the plurality of temperatures including at least the first temperature and the second temperature; and
determine a relation between optical power output and temperature for each pair of magnetic recording head and laser diode for a plurality of currents.

13. A method for operating a data storage device, comprising:
setting at least one laser diode to a first temperature;
applying a first forward bias to the at least one laser diode such that the at least one laser diode is in a lasing state, wherein applying the first forward bias further comprises supplying a first current to the at least one laser diode;
measuring a first optical power output of the at least one laser diode, wherein the first optical power output corresponds to the first temperature and the first current;
setting the at least one laser diode to a second temperature;
measuring a second optical power output of the at least one laser diode, wherein the second optical power output corresponds to the second temperature and the first current; and
determining an output profile for the at least one laser diode for the first current, based at least in part on the respective optical power output at the first temperature and the second temperature.

14. The method of claim 13, further comprising:
setting the at least one laser diode to a third temperature; and
measuring a third optical power output of the at least one laser diode, wherein the third optical power output corresponds to the third temperature and the first current; and
wherein determining the output profile for the at least one laser diode is further based on the third optical power output at the third temperature.

15. The method of claim 14, wherein determining the output profile for the at least one laser diode is based at least in part on sweeping the at least one laser diode through a plurality of temperatures and measuring a corresponding optical power output for each of the plurality of temperatures, including at least the first, the second, and the third temperatures, and wherein the output profile is specific to the first current.

16. The method of claim 14, wherein:
setting the at least one laser diode to the first temperature comprises applying a first reverse bias to the at least one laser diode to preheat the at least one laser diode to the first temperature; and
setting the at least one laser diode to the second temperature comprises applying a second reverse bias to the at least one laser diode to preheat the at least one laser diode to the second temperature.

17. The method of claim 13, further comprising:
determining one or more other output profiles for the at least one laser diode, based at least in part on sweeping the at least one laser diode through a plurality of temperatures and measuring a corresponding optical power output for each of the plurality of temperatures, wherein each of the one or more output profiles is associated with one or more of a different forward bias and a different current.

18. The method of claim 17, further comprising:
selecting an optical power output for a write operation, wherein the write operation is associated with a steady state temperature;
initiating the write operation by,
activating a magnetic recording head corresponding to a first one of the at least one laser diode,
applying a forward bias to the first laser diode, and
supplying a first laser current to the first laser diode;
monitoring an optical power output of the first laser diode; and
determining whether the optical power output of the first laser diode is different from the optical power output selected for the write operation.

19. The method of claim 18, further comprising:
adjusting the first laser current supplied to the first laser diode, based at least in part on determining the optical power output of the first laser diode is different from the optical power output selected for the write operation, and wherein the adjusting the first laser current is based at least in part on determining the one or more output profiles.

20. One or more processing devices, comprising:
means for setting at least one laser diode to a first temperature;
means for applying a first forward bias to the at least one laser diode such that the at least one laser diode is in a lasing state, wherein applying the first forward bias further comprises supplying a first current to the at least one laser diode;
means for measuring a first optical power output of the at least one laser diode, wherein the first optical power output corresponds to the first temperature and the first current;
means for setting the at least one laser diode to a second temperature;
means for measuring a second optical power output of the at least one laser diode, wherein the second optical power output corresponds to the second temperature and the first current; and
means for determining an output profile for the at least one laser diode for the first current, based at least in part on the respective optical power output at the first temperature and the second temperature.
